(19) United States
(12) Patent Application Publication
(10) Pub. No.: US 2022/0341038 A1
(43) Pub. Date: Oct. 27, 2022

(54) RAW MATERIAL SUPPLY APPARATUS AND RAW MATERIAL SUPPLY METHOD

(71) Applicant: TOKYO ELECTRON LIMITED, Tokyo (JP)

(72) Inventors: Tsuneyuki OKABE, Nirasaki-shi, Yamanashi (JP); Eiichi KOMORI, Nirasaki-shi, Yamanashi (JP)

(21) Appl. No.: 17/761,091

(22) PCT Filed: Sep. 15, 2020
(86) PCT No.: PCT/JP2020/034970

§ 371 Date: Mar. 16, 2022

(30) Foreign Application Priority Data
Sep. 24, 2019 (JP) 2019-173419

(51) Int. Cl. C23C 16/44; C23C 16/02; C23C 16/452; C23C 16/455

(52) U.S. Cl. CPC C23C 16/4412; C23C 16/0218; C23C 16/452; C23C 16/45512

(57) ABSTRACT

A raw material supply apparatus includes: a container configured to store a solution obtained by dissolving a first solid raw material in a solvent or a dispersion system obtained by dispersing the first solid raw material in a dispersion medium; an injection part configured to spray the solution or the dispersion system to inject the solution or the dispersion system into the container; an exhaust port configured to exhaust an inside of the container; a heating part configured to heat a second solid raw material formed by removing the solvent or the dispersion medium from the solution or the dispersion system; and a deposition part provided between the injection part and the exhaust port in the container and configured to deposit the second solid raw material.

### TECHNICAL FIELD

The present disclosure relates to a raw material supply apparatus and a raw material supply method.

### BACKGROUND

A technique of producing a gas is known, in which after dissolving a solid raw material in a solvent and spraying it into a process chamber, an interior of the process chamber is heated such that the solvent is removed and the solid raw material remains, and then the interior of the process chamber is heated to sublimate the solid raw material (see, e.g., Patent Document 1).

### PRIOR ART DOCUMENT

Patent Document

Japanese Laid-open Publication No. 2004-115831

The present invention provides a technique capable of improving an operation rate of a processing apparatus.

### SUMMARY

A raw material supply apparatus according to an embodiment of the present disclosure includes: a container configured to store a solution obtained by dissolving a first solid raw material in a solvent or a dispersion system obtained by dispersing the first solid raw material in a dispersion medium; an injection part configured to spray the solution or the dispersion system to inject the solution or the dispersion system into the container; an exhaust port configured to exhaust an inside of the container; a heating part configured to heat a second solid raw material formed by removing the solvent or the dispersion medium from the solution or the dispersion system; and a deposition part provided between the injection part and the exhaust port in the container and configured to deposit the second solid raw material.

According to the present disclosure, it is possible to improve an operation rate of a processing apparatus.

### BRIEF DESCRIPTION OF DRAWINGS

FIG. 1 is a view showing an example of a raw material supply system.

FIG. 2A is a view showing an example of a raw material source.

FIG. 2B is a view showing an example of a raw material source.

FIG. 2C is a view showing an example of a raw material source.

FIG. 3 is a view showing another example of the raw material source.

FIG. 4 is a view showing a first configuration example of a raw material supply apparatus.

FIG. 5 is a view showing a second configuration example of the raw material supply apparatus.

FIG. 6 is a view showing a third configuration example of the raw material supply apparatus.

FIG. 7 is a view showing a fourth configuration example of the raw material supply apparatus.

FIG. 8 is a view showing a fifth configuration example of the raw material supply apparatus.

FIG. 9 is a view showing a sixth configuration example of the raw material supply apparatus.

FIG. 10 is a view (1) for explaining operation of the raw material supply system.

FIG. 11 is a view (2) for explaining operation of the raw material supply system.

### DETAILED DESCRIPTION

Non-limiting exemplary embodiments of the present disclosure will now be described with reference to the accompanying drawings. Throughout the accompanying drawings, the same or corresponding members or parts are denoted by the same or corresponding reference numerals, and redundant explanation thereof will be omitted.

### [Raw Material Supply System]

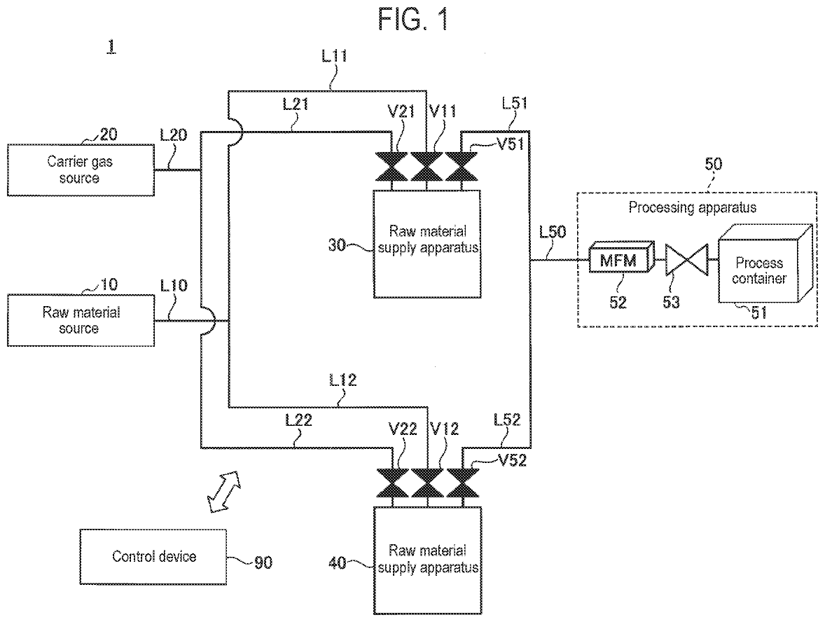

FIG. 1 is a view showing an example of a raw material supply system. As shown in FIG. 1, a raw material supply system 1 includes a raw material source 10, a carrier gas source 20, raw material supply apparatuses 30 and 40, a processing apparatus 50, and a control device 90.

The raw material source 10 supplies a solution, which is obtained by dissolving a first solid raw material in a solvent, or a slurry, which is obtained by dispersing the first solid raw material in a solvent (dispersion medium), to the raw material supply apparatuses 30 and 40. The raw material source 10 may be any source as long as it can supply the solution or slurry to the raw material supply apparatuses 30 and 40, and its form is not particularly limited.

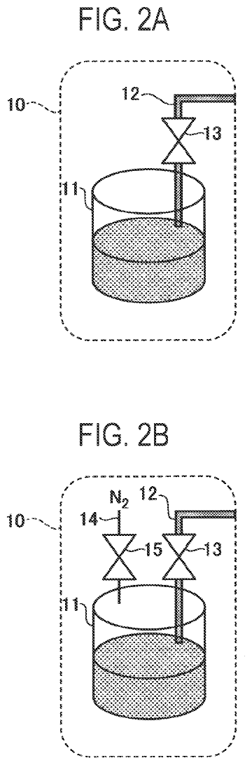

FIGS. 2A to 2C are views showing examples of the raw material source 10, and show configuration examples in which the raw material source 10 supplies a solution, which is obtained by dissolving the first solid raw material in a solvent, to the raw material supply apparatuses 30 and 40. For example, as shown in FIG. 2A, the raw material source 10 has a tank 11 filled with the solution, a pipe 12 inserted into the tank 11 from above, and a valve 13 interposed in the pipe 12. In the raw material source 10 shown in FIG. 2A, the solution is supplied from the pipe 12 under pressure by the weight of the solution filled in the tank 11. Further, for example, as shown in FIG. 2B, the raw material source 10 may have a tank 11 filled with the solution, pipes 12 and 14 inserted into the tank 11 from above, and valves 13 and 15 interposed in the pipes 12 and 14, respectively. In the raw material source 10 shown in FIG. 2B, the inside of the tank 11 is pressurized by supplying an inert gas such as nitrogen (N₂) into the tank 11 from the pipe 14, so that the solution is supplied from the pipe 12. Further, for example, as shown in FIG. 2C, the raw material source 10 may have a tank 11 filled with the solution, a pipe 16 connected below the tank 11, and a valve 17 interposed in the pipe 16. In the raw material source 10 shown in FIG. 2C, the solution is supplied from below the tank 11 through the pipe 16 by using natural fall due to gravity.

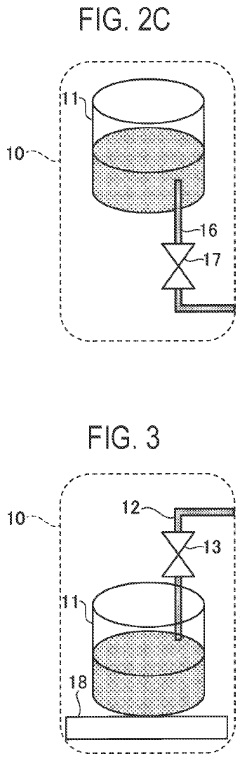

FIG. 3 is a view showing another example of the raw material source 10, and shows a configuration example in which the raw material source 10 supplies a slurry, which is obtained by dispersing the first solid raw material in a solvent, to the raw material supply apparatuses 30 and 40. For example, as shown in FIG. 3, the raw material source 10 has a tank 1I filled with the slurry, a pipe 12 inserted into the tank 11 from above, a valve 13 interposed in the pipe 12, and a vibrating table 18 that vibrates the tank 11. In the raw material source 10 shown in FIG. 3, the tank 11 placed on the vibrating table 18 is vibrated and pressurized by the weight of the slurry filled in the tank 11 to supply the slurry from the pipe 12.

The raw material source 10 is connected to the raw material supply apparatus 30 via pipes L10 and L11, and supplies the solution, which is obtained by dissolving the first solid raw material in the solvent, or the slurry, which is obtained by dispersing the first solid raw material in the solvent, to the raw material supply apparatus 30 through the pipes L10 and L11. A valve V11 is interposed in the pipe L11. When the valve V11 is opened, the solution or slurry is supplied from the raw material source 10 to the raw material supply apparatus 30, and when the valve V11 is closed, the supply of the solution or slurry from the raw material source 10 to the raw material supply apparatus 30 is cut off. Further, the pipe L11 may be provided with a flow rate controller (not shown) for controlling a flow rate of the solution or slurry flowing through the pipe L11, an additional valve, and the like.

Further, the raw material source 10 is connected to the raw material supply apparatus 40 via pipes L10 and L12, and supplies the solution, which is obtained by dissolving the first solid raw material in the solvent, or the slurry, which is obtained by dispersing the first solid raw material in the solvent, to the raw material supply apparatus 40 through the pipes L10 and L12. A valve V12 is interposed in the pipe L12. When the valve V12 is opened, the solution or slurry is supplied from the raw material source 10 to the raw material supply apparatus 40, and when the valve V12 is closed, the supply of the solution or slurry from the raw material source 10 to the raw material supply apparatus 40 is cut off. Further, the pipe L12 may be provided with a flow rate controller (not shown) for controlling a flow rate of the solution or slurry flowing through the pipe L12, an additional valve, and the like.

The first solid raw material is not particularly limited, but may be, for example, an organic metal complex containing a metal element such as strontium (Sr), molybdenum (Mo), ruthenium (Ru), zirconium (Zr), hafnium (Hf), tungsten (W), or aluminum (Al), or chloride containing a metal element such as tungsten (W) or aluminum (Al).

As the solvent, it is sufficient if the first solid raw material can be dissolved or dispersed to form a solution or slurry. For example, the solvent may be hexane.

The carrier gas source 20 supplies a carrier gas to the raw material supply apparatuses 30 and 40. The carrier gas source 20 is connected to the raw material supply apparatus 30 via pipes L20 and L21, and supplies the carrier gas to the raw material supply apparatus 30 through the pipes L20 and L21. A valve V21 is interposed in the pipe L21. When the valve V21 is opened, the carrier gas is supplied from the carrier gas source 20 to the raw material supply apparatus 30, and when the valve V21 is closed, the supply of the carrier gas from the carrier gas source 20 to the raw material supply apparatus 30 is cut off. Further, the pipe L21 may be provided with a flow rate controller (not shown) for controlling a flow rate of the carrier gas flowing through the pipe L21, an additional valve, and the like.

Further, the carrier gas source 20 is connected to the raw material supply apparatus 40 via pipes L20 and L22, and supplies the carrier gas to the raw material supply apparatus 40 through the pipes L20 and L22. A valve V22 is interposed in the pipe L22. When the valve V22 is opened, the carrier gas is supplied from the carrier gas source 20 to the raw material supply apparatus 40, and when the valve V22 is closed, the supply of the carrier gas from the carrier gas source 20 to the raw material supply apparatus 40 is cut off. Further, the pipe L22 may be provided with a flow rate controller (not shown) for controlling a flow rate of the carrier gas flowing through the pipe L22, an additional valve, and the like.

The carrier gas is not particularly limited, but may be, for example, an inert gas such as nitrogen (N₂) or argon (Ar).

The raw material supply apparatuses 30 and 40 store the solution obtained by dissolving the first solid raw material in the solvent or the slurry obtained by dispersing the first solid raw material in the solvent, which is supplied from the raw material source 10. The raw material supply apparatus 30 and the raw material supply apparatus 40 are provided in parallel, and may have the same configuration, for example. Hereinafter, the raw material supply apparatus 30 will be described by way of example, but the raw material supply apparatus 40 may have the same configuration as the raw material supply apparatus 30.

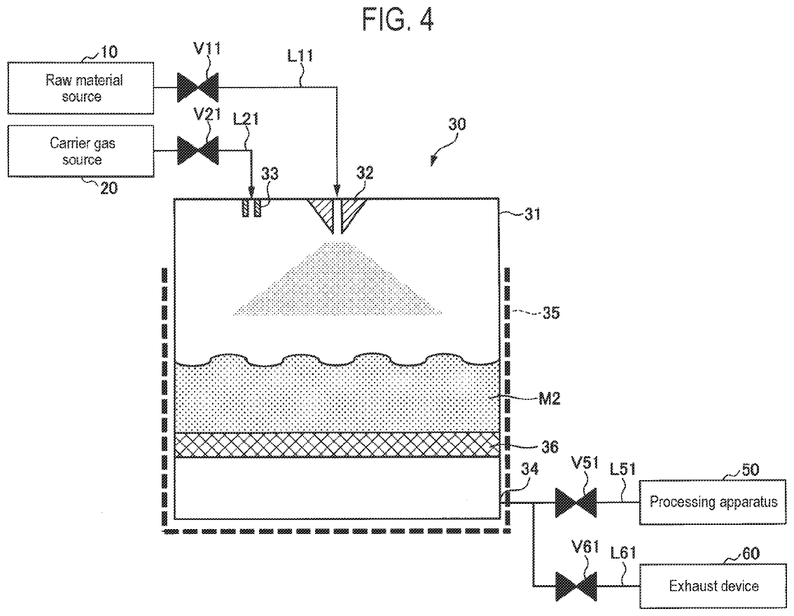

FIG. 4 is a view showing a first configuration example of the raw material supply apparatus 30. As shown in FIG. 4, the raw material supply apparatus 30 has a container 31, a raw material injection part 32, a carrier gas injection part 33, an exhaust port 34, a heating part 35, and a deposition part 36.

The container 31 stores the solution or slurry.

The raw material injection part 32 sprays the solution or slurry supplied from the raw material source 10 through the pipe L11 to inject the solution or slurry into the container 31. The raw material injection part 32 vaporizes the solvent before the solution or slurry reaches the deposition part 36, by spraying the solution or slurry. The raw material injection part 32 may be, for example, a spray nozzle.

The carrier gas injection part 33 injects the carrier gas, which is supplied from the carrier gas source 20 through the pipe L21, into the container 31.

The exhaust port 34 is provided at a lower portion of the container 31 and exhausts the inside of the container 31. The processing apparatus 50 is connected to the exhaust port 34 via a pipe L51. Further, a valve V51 is interposed in the pipe L51. An exhaust device 60 is connected between the exhaust port 34 and the valve V51 in the pipe L51 via a pipe L61. When a valve V61 is opened, the inside of the container 31 can be exhausted by the exhaust device 60.

The heating part 35 heats a solid raw material (hereinafter, also referred to as a “second solid raw material M2”), which is formed by removing the solvent from the solution or slurry, to sublimate the second solid raw material M2 to generate a reactive gas. The heating part 35 may be, for example, a heater disposed so as to cover a bottom portion and an outer periphery of the container 31. The heating part 35 is configured to be capable of heating the inside of the container 31 to a temperature at which the second solid raw material M2 can be sublimated to generate the reactive gas.

The deposition part 36 is provided between the raw material injection part 32 and the exhaust port 34 in the container 31, and deposits the second solid raw material M2. It is desirable that the deposition part 36 is disposed so as to partition the inside of the container 31 into a region including the raw material injection part 32 and a region including the exhaust port 34. With such a configuration, when the reactive gas generated by sublimating the second solid raw material M2 is supplied to the processing apparatus 50 from the exhaust port 34, impurities such as particles are captured by the deposition part 36, so that it is possible to prevent the impurities such as particles from being supplied into the processing apparatus 50. The deposition part 36 may be made of a material that allows the reactive gas to pass therethrough and captures the second solid raw material M2 and the impurities such as particles. For example, the deposition part 36 is made of a porous material. The porous material may be a porous metallic material such as a sintered body of stainless steel, or a porous ceramic material.

In the raw material supply apparatus 30 described above, by opening the valve V11 and spraying and injecting the solution or slurry into the container 31 from the raw material injection part 32, the solvent is vaporized before the solution or slurry reaches the deposition part 36, and the second solid raw material M2 is deposited on the deposition part 36. In this way, in the raw material supply apparatus 30, the solution or slurry is deposited and stored in a solid state in the deposition part 36, so that an amount of storable solid raw material per fixed volume increases.

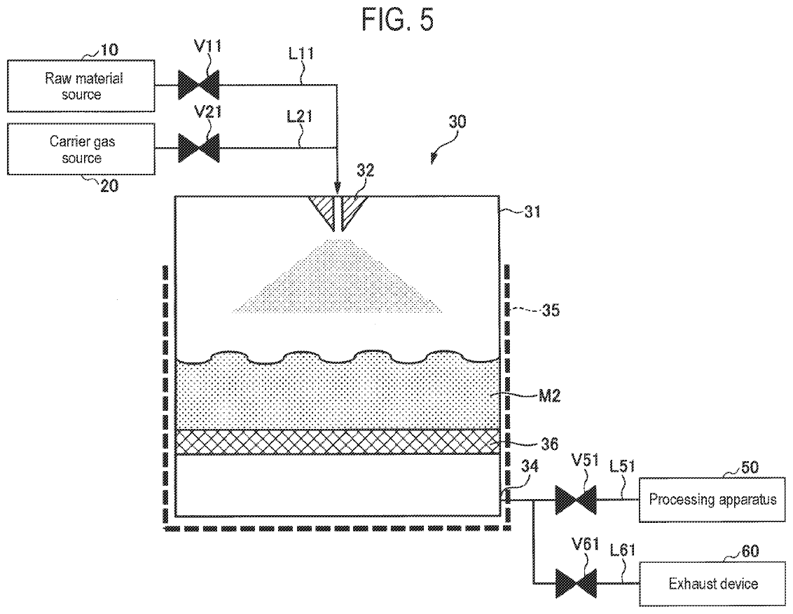

Further, in the example of FIG. 4, the case where the raw material injection part 32 and the carrier gas injection part 33 are separately provided has been described, but the present disclosure is not limited thereto. For example, as shown in FIG. 5, the raw material injection part 32 may have the function of the carrier gas injection part 33. In the example of FIG. 5, the pipe L21 is connected between the valve V11 in the pipe L11 and the raw material injection part 32, and the carrier gas is injected from the raw material injection part 32 into the container 31. FIG. 5 is a view showing a second configuration example of the raw material supply apparatus 30.

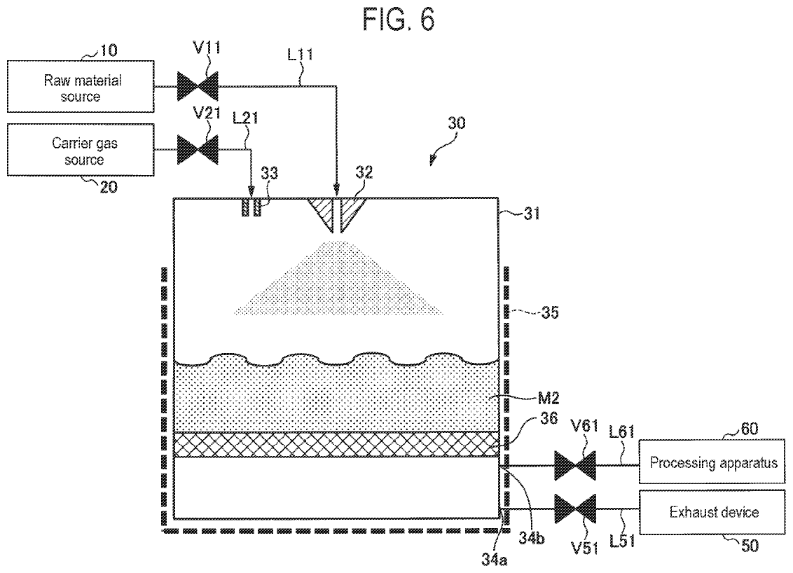

Further, in the example of FIG. 4, the case where the processing apparatus 50 and the exhaust device 60 are connected to one exhaust port 34 has been described, but the present disclosure is not limited thereto. For example, as shown in FIG. 6, the container 31 may be provided with two exhaust ports 34a and 34b, and the processing apparatus 50 and the exhaust device 60 may be connected to the exhaust ports 34a and 34b, respectively. In the example of FIG. 6, the processing apparatus 50 is connected to the exhaust port 34a via the pipe L51 having the valve V51 interposed therein, and the exhaust device 60 is connected to the exhaust port 34b via the pipe L61 having the valve V61 interposed therein. FIG. 6 is a view showing a third configuration example of the raw material supply apparatus 30.

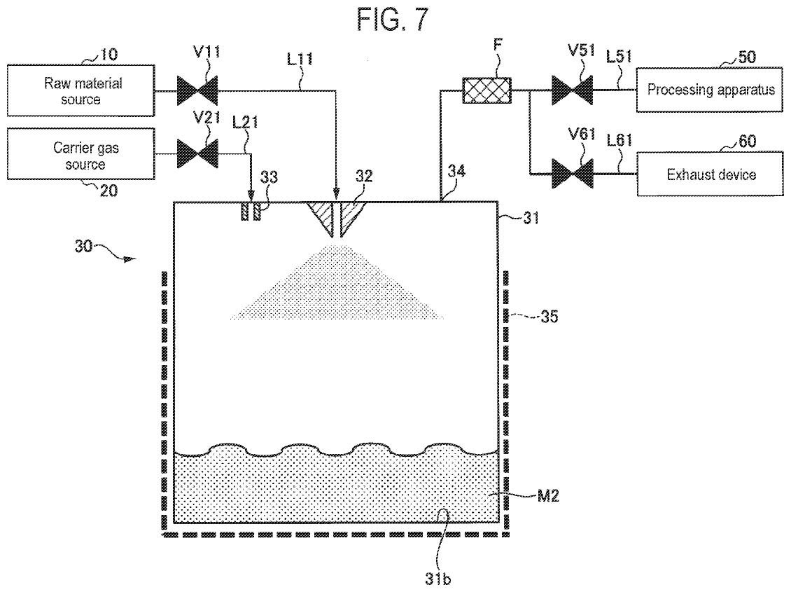

FIG. 7 is a view showing a fourth configuration example of the raw material supply apparatus 30. The raw material supply apparatus 30 shown in FIG. 7 is different from the raw material supply apparatus 30 shown in FIG. 4 in that the deposition part 36 is not provided in the container 31, the exhaust port 34 is provided at an upper portion of the container 31, and a filter F is interposed in the pipe L51 connected to the exhaust port 34. Hereinafter, the differences from the raw material supply apparatus 30 shown in FIG. 4 will be mainly described.

As shown in FIG. 7, the raw material supply apparatus 30 has the container 31, the raw material injection part 32, the carrier gas injection part 33, the exhaust port 34, and the heating part 35. The container 31, the raw material injection part 32, the carrier gas injection part 33, and the heating part 35 are the same as those of the raw material supply apparatus 30 shown in FIG. 4.

The exhaust port 34 is provided at the upper portion of the container 31 and exhausts the inside of the container 31. The processing apparatus 50 is connected to the exhaust port 34 via the pipe L51. Further, the valve V51 is interposed in the pipe L51. The exhaust device 60 is connected between the exhaust port 34 and the valve V51 in the pipe L51 via the pipe L61. When the valve V61 is opened, the inside of the container 31 can be exhausted by the exhaust device 60. Further, the filter F is interposed between the exhaust port 34 and the valve V51 in the pipe L51. In the example shown in FIG. 7, the deposition part 36 is not provided between the raw material injection part 32 and the exhaust port 34. Thus, together with the reactive gas generated by sublimating the second solid raw material M2 in the container 31, impurities such as particles flow into the pipe L51 through the exhaust port 34. The filter F captures the impurities such as particles flowing into the pipe L51. Therefore, it is possible to prevent the impurities such as particles from being supplied to the processing apparatus 50. The filter F may be made of a material that allows the reactive gas to pass therethrough and captures the second solid raw material M2 and the impurities such as particles. For example, the filter F may be made of the same material as the deposition part 36.

In the raw material supply apparatus 30 described above, by opening the valve V11 and spraying and injecting the solution or slurry into the container 31 from the raw material injection part 32, the solvent is vaporized before the solution or slurry reaches a bottom portion 31b of the container 31, and the second solid raw material M2 is deposited on the bottom portion 31b of the container 31. With this configuration, in the raw material supply apparatus 30, the solution or slurry is deposited and stored in a solid state on the bottom portion 31b of the container 31, so that an amount of storable solid raw material per fixed volume increases.

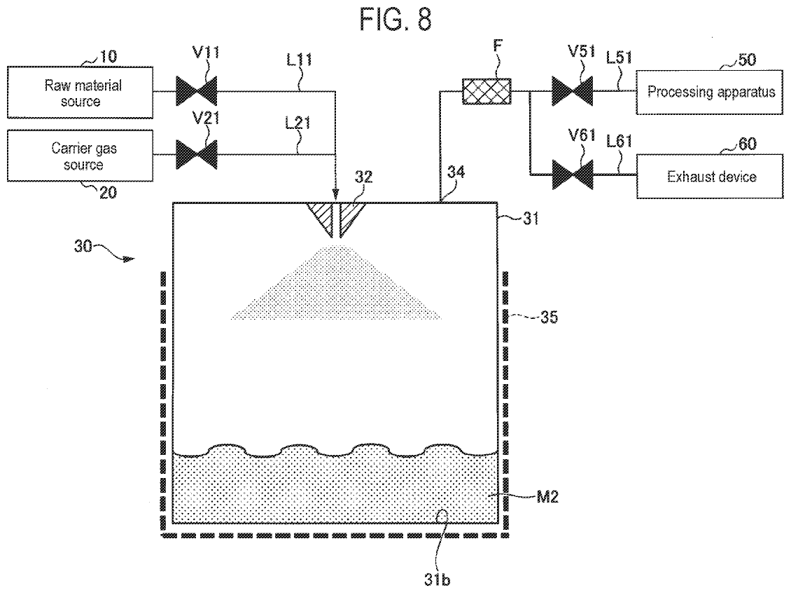

In the example of FIG. 7, the case where the raw material injection part 32 and the carrier gas injection part 33 are separately provided has been described, but the present disclosure is not limited thereto. For example, as shown in FIG. 8, the raw material injection part 32 may have the function of the carrier gas injection part 33. In the example of FIG. 8, the pipe L21 is connected between the valve V11 in the pipe L11 and the raw material injection part 32, and the carrier gas is injected from the raw material injection part 32 into the container 31. FIG. 8 is a view showing a fifth configuration example of the raw material supply apparatus 30.

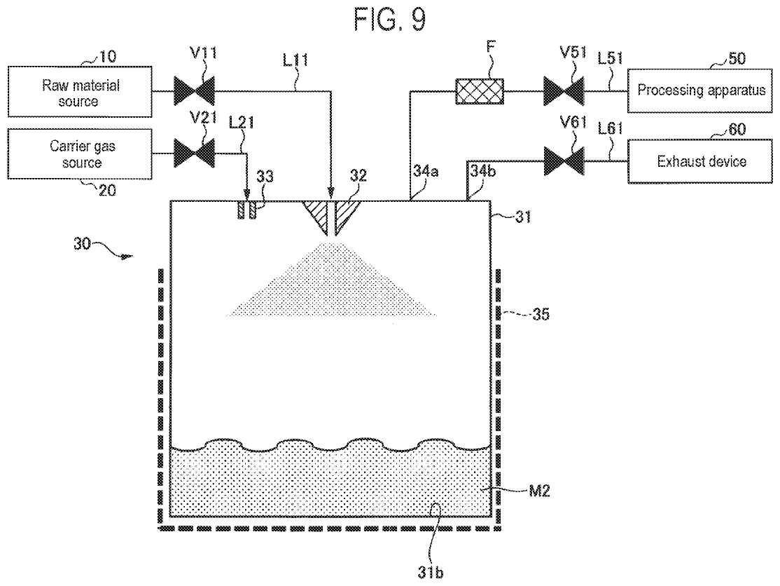

Further, in the example of FIG. 7, the case where the processing apparatus 50 and the exhaust device 60 are connected to one exhaust port 34 has been described, but the present disclosure is not limited thereto. For example, as shown in FIG. 9, the container 31 may be provided with two exhaust ports 34a and 34b, and the processing apparatus 50 and the exhaust device 60 may be connected to the exhaust ports 34a and 34b, respectively. In the example of FIG. 9, the processing apparatus 50 is connected to the exhaust port 34a via the pipe L51 having the valve V51 and the filter F interposed therein, and the exhaust device 60 is connected to the exhaust port 34b via the pipe L61 having the valve V61 interposed therein. FIG. 9 is a view showing a sixth configuration example of the raw material supply apparatus 30.

The processing apparatus 50 is connected to the raw material supply apparatus 30 via the pipe L51 and a pipe L50, and the reactive gas generated by heating and sublimating the second solid raw material M2 in the raw material supply apparatus 30 is supplied to the processing apparatus 50. The valve V51 is interposed in the pipe L51. When the valve V51 is opened, the reactive gas is supplied from the raw material supply apparatus 30 to the processing apparatus 50, and when the valve V51 is closed, the supply of the reactive gas from the raw material supply apparatus 30 to the processing apparatus 50 is cut off.

Further, the processing apparatus 50 is connected to the raw material supply apparatus 40 via a pipe L52 and the pipe L50, and the reactive gas generated by heating and sublimating the second solid raw material M2 in the raw material supply apparatus 40 is supplied to the processing apparatus 50. A valve V52 is interposed in the pipe L52. When the valve V52 is opened, the reactive gas is supplied from the raw material supply apparatus 40 to the processing apparatus 50, and when the valve V52 is closed, the supply of the reactive gas from the raw material supply apparatus 40 to the processing apparatus 50 is cut off.

The processing apparatus 50 executes various processes such as a film-forming process on a substrate such as a semiconductor wafer by using the reactive gas supplied from the raw material supply apparatuses 30 and 40. The processing apparatus 50 includes a process container 51, a mass flow meter 52, and a valve 53. The process container 51 accommodates one or more substrates. The mass flow meter 52 is interposed in the pipe L50 and measures a flow rate of the reactive gas flowing through the pipe L50. The valve 53 is interposed in the pipe L50. When the valve V53 is opened, the reactive gas is supplied from the raw material supply apparatuses 30 and 40 to the process container 51, and when the valve V53 is closed, the supply of the reactive gas from the raw material supply apparatuses 30 and 40 to the process container 51 is cut off.

The control device 90 controls individual components of the raw material supply system. For example, the control device 90 controls operations of the raw material source 10, the carrier gas source 20, the raw material supply apparatuses 30 and 40, the processing apparatus 50, and the like. Further, the control device 90 controls opening and closing of various valves. The control device 90 may be, for example, a computer.

### [Operation of Raw Material Supply System]

An example of an operation (raw material supply method) of the raw material supply system 1 will be described. In the raw material supply system 1, the control device 90 controls the opening and closing of the valves V11, V12, V21, V22, V51, and V52, so that one of the two raw material supply apparatuses 30 and 40 provided in parallel supplies the reactive gas to the processing apparatus 50, and the other thereof fills the solid raw material. Hereinafter, an example of the operation of the raw material supply system 1 will be described in detail.

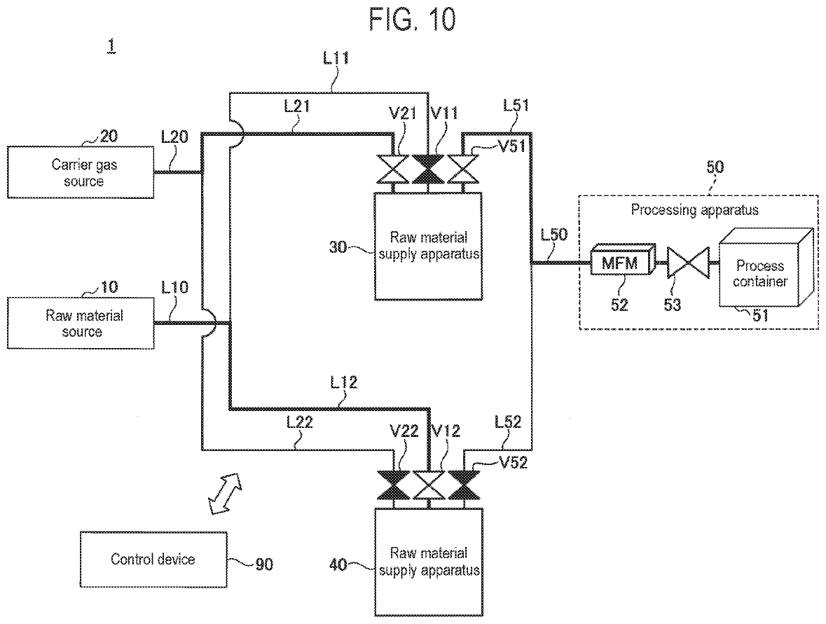

First, a case where the raw material supply apparatus 30 supplies the reactive gas to the processing apparatus 50 and the raw material supply apparatus 40 fills the solid raw material will be described with reference to FIG. 10. FIG. 10 is a view for explaining an operation of the raw material supply system 1. In FIG. 10, pipes through which the carrier gas, the solution or the slurry, and the reactive gas are flowing are indicated by a thick solid line, and pipes through which the carrier gas, the solution or the slurry, and the reactive gas are not flowing are indicated by a thin solid line. Description will be given by assuming that, in an initial state of the raw material supply system 1, all the valves V11, V12, V21, V22, V51, and V52 are closed and the second solid raw material M2 is stored in the raw material supply apparatus 30, as shown in FIG. 1.

The control device 90 controls the heating part 35 (see FIG. 4) of the raw material supply apparatus 30 to heat and sublimate the second solid raw material M2 (see FIG. 4) deposited on the deposition part 36 in the container 31, thereby generating the reactive gas. Further, the control device 90 opens the valves V21 and V51. As a result, the carrier gas is injected from the carrier gas source 20 into the container 31 of the raw material supply apparatus 30 via the pipes L20 and L21, and the reactive gas generated in the container 31, together with the carrier gas, is supplied to the processing apparatus 50 through the pipes L51 and L50. In addition, the control device 90 opens the valve V12. As a result, the solution or slurry is injected from the raw material source 10 into the raw material supply apparatus 40 through the pipes L10 and L12, and the second solid raw material M2 is deposited on the deposition part in the container of the raw material supply apparatus 40. As described above, when the valves V12, V21, and V51 are in the opened state and the valves V11, V22, and V52 are in the closed state, the raw material supply apparatus 30 supplies the reactive gas to the processing apparatus 50, and the raw material supply apparatus 40 fills the solid raw material. FIG. 10 shows the state in which the valves V12, V21, and V51 are opened and the valves V11, V22, and V52 are closed.

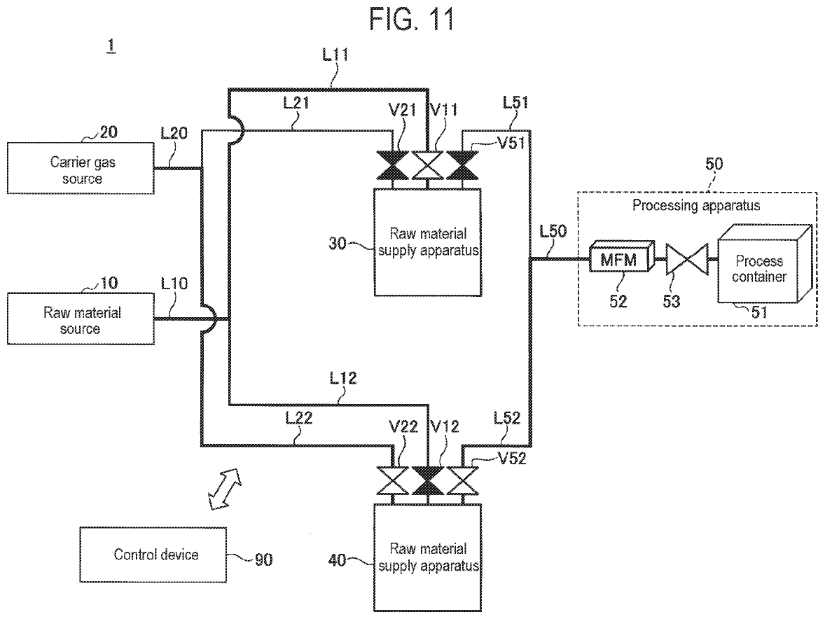

Next, a case where the state (see FIG. 10) in which the raw material supply apparatus 30 supplies the reactive gas to the processing apparatus 50 is switched to a state in which the raw material supply apparatus 40 supplies the reactive gas to the processing apparatus 50 and the raw material supply apparatus 30 fills the solid raw material will be described with reference to FIG. 11. FIG. 11 is a view for explaining an operation of the raw material supply system 1. In FIG. 11, pipes through which the carrier gas, the solution or slurry, and the reactive gas are flowing are indicated by a thick solid line, and pipes through which the carrier gas, the solution or slurry, and the reactive gas are not flowing are indicated by a thin solid line.

First, the control device 90 turns off the heating part 35 of the raw material supply apparatus 30 and closes the valves V21, V51, and V12. As a result, the supply of the reactive gas from the raw material supply apparatus 30 to the processing apparatus 50 is stopped.

Subsequently, the control device 90 controls the heating part of the raw material supply apparatus 40 to heat and sublimate the second solid raw material M2 deposited on the deposition part in the container, thereby generating the reactive gas. Further, the control device 90 opens the valves V22 and V52. As a result, the carrier gas is injected from the carrier gas source 20 into the raw material supply apparatus 40 through the pipes L20 and L22, and the reactive gas generated in the container, together with the carrier gas, is supplied to the processing apparatus 50 through the pipes L52 and L50. Further, the control device 90 opens the valve V11. As a result, the solution or slurry is injected from the raw material source 10 into the raw material supply apparatus 30 through the pipes L10 and L11, and the second solid raw material M2 is deposited on the deposition part 36 in the container 31 of the raw material supply apparatus 30. As described above, when the valves V11, V22, and V52 are in the opened state and the valves V12, V21, and V51 are in the closed state, the raw material supply apparatus 40 supplies the reactive gas to the processing apparatus 50, and the raw material supply apparatus 30 fills the solid raw material. FIG. 11 shows the state in which the valves V11, V22, and V52 are opened and the valves V12, V21, and V51 are closed.

As described above, in the raw material supply system 1, the control device 90 controls the opening and closing of the valves V11, V12, V21, V22, V51, and V52 so that one of the two raw material supply apparatuses 30 and 40 supplies the reactive gas to the processing apparatus 50 and the other thereof fills the solid raw material. As a result, since the raw material can be automatically replenished to the raw material supply apparatuses 30 and 40, continuous operation capacity of the processing apparatus 50 can be improved, which improves the operation rate of the processing apparatus 50.

In addition, in the raw material supply system 1, the solution or slurry is sprayed and injected into the container 31 from the raw material injection part 32 so that the solvent is vaporized and deposited as the second solid raw material M2 before the solution or slurry reaches the deposition part 36 or the bottom portion 31b of the container 31. As described above, in the raw material supply system 1, since the solution or slurry injected into the container 31 is deposited and stored in a solid state on the deposition part 36 or the bottom portion 31b of the container 31, the amount of storable solid raw material per fixed volume can be increased. In contrast, when the solution is stored in a liquid state in the container 31, a size of the container 31 depends on solubility of the solid raw material in the solvent. Therefore, when the solid raw material has low solubility, a maximum amount of the solid raw material that can be stored in the container 31 is lowered.

In addition, in the raw material supply system 1, the solution, which is obtained by dissolving the solid raw material in the solvent, or the slurry, which is obtained by dispersing the solid raw material in the solvent, is sprayed to vaporize the solvent and after being deposited as the solid raw material M2 on the deposition part 36, the second solid raw material M2 is sublimated and supplied to the processing apparatus 50. This simplifies a flow rate control and facilitates controlling a large-scale flow rate.

It should be considered that the embodiments disclosed this time are exemplary in all respects, not restrictive. The above embodiments may be omitted, replaced, or changed in various forms without departing from the appended claims and the gist thereof.

In the above embodiment, the solution, which is obtained by dissolving the first solid raw material in the solvent, or the slurry which is obtained by dispersing the first solid raw material in the dispersion medium, has been described as an example, but the present disclosure is not limited thereto. For example, instead of the slurry, a dispersion system such as a colloidal solution which is obtained by dispersing the first solid raw material in a dispersion medium can also be used. For example, by using the colloidal solution, it is possible to fill a precursor having a higher concentration than using a solution or a slurry. The dispersion system includes a slurry and a colloid as the subordinate concept. The slurry is also referred to as a suspension. The colloid includes a colloidal solution as the subordinate concept. The colloidal solution is also referred to as a sol.

This international application claims priority based on Japanese Patent Application No. 2019-173419, filed on Sep. 24, 2019, the entire contents of which are incorporated herein by reference.

### EXPLANATION OF REFERENCE NUMERALS

1: raw material supply system. 30: raw material supply apparatus, 31: container, 32: raw material injection part, 34: exhaust port, 35: heating part, 36: deposition part, 40: raw material supply apparatus, 50: processing apparatus, 60: exhaust device, M1: first solid raw material, M2: second solid raw material

1-13. (canceled)

14. A raw material supply apparatus comprising:
a container configured to store a solution obtained by dissolving a first solid raw material in a solvent or a dispersion system obtained by dispersing the first solid raw material in a dispersion medium;
an injection part configured to spray the solution or the dispersion system to inject the solution of the dispersion system into the container;
an exhaust port configured to exhaust an inside of the container;
a heating part configured to heat a second solid raw material formed by removing the solvent or the dispersion medium from the solution or the dispersion system; and
a deposition part provided between the injection part and the exhaust port in the container and configured to deposit the second solid raw material.

15. The raw material supply apparatus of claim 14, wherein the deposition part partitions the inside of the container into a region including the injection part and a region including the exhaust port.

16. The raw material supply apparatus of claim 15, wherein the deposition part is made of a porous material.

17. The raw material supply apparatus of claim 16, wherein the injection part vaporizes the solvent or the dispersion medium before the solution or the dispersion system reaches the deposition part.

18. The raw material supply apparatus of claim 17, wherein the exhaust port is connected to a processing apparatus that performs a process using a reactive gas obtained by heating and sublimating the second solid raw material.

19. The raw material supply apparatus of claim 18, wherein the exhaust port is connected to an exhaust device that exhausts the inside of the container.

20. The raw material supply apparatus of claim 14, wherein the deposition part is made of a porous material.

21. The raw material supply apparatus of claim 14, wherein the injection part vaporizes the solvent or the dispersion medium before the solution or the dispersion system reaches the deposition part.

22. The raw material supply apparatus of claim 14, wherein the exhaust port is connected to a processing apparatus that performs a process using a reactive gas obtained by heating and sublimating the second solid raw material.

23. The raw material supply apparatus of claim 14, wherein the exhaust port is connected to an exhaust device that exhausts the inside of the container.

24. A raw material supply apparatus comprising:
a container configured to store a dispersion system obtained by dispersing a first solid raw material in a dispersion medium;
an injection part configured to spray the dispersion system to inject the dispersion system into the container; and
a heating part configured to heat a second solid raw material formed by removing the dispersion medium from the dispersion system.

25. The raw material supply apparatus of claim 24, further comprising:
an exhaust port configured to exhaust an inside of the container; and
a deposition part provided between the injection part and the exhaust port in the container and configured to deposit the second solid raw material.

26. The raw material supply apparatus of claim 25, wherein the deposition part is made of a porous material.

27. The raw material supply apparatus of claim 26, wherein the injection part vaporizes the dispersion medium before the dispersion system reaches the deposition part.

28. The raw material supply apparatus of claim 27, wherein the exhaust port is connected to a processing apparatus that performs a process using a reactive gas obtained by heating and sublimating the second solid raw material.

29. The raw material supply apparatus of claim 28, wherein the exhaust port is connected to an exhaust device that exhausts the inside of the container.

30. The raw material supply apparatus of claim 24, wherein the injection part vaporizes the dispersion medium before the dispersion system reaches the deposition part.

31. The raw material supply apparatus of claim 24, wherein the exhaust port is connected to a processing apparatus that performs a process using a reactive gas obtained by heating and sublimating the second solid raw material.

32. The raw material supply apparatus of claim 24, wherein the exhaust port is connected to an exhaust device that exhausts the inside of the container.

33. A raw material supply method comprising:
spraying a solution, which is obtained by dissolving a first solid raw material in a solvent, or a dispersion system, which is obtained by dispersing the first solid raw material in a dispersion medium, into a container to vaporize and remove the solvent or the dispersion medium from the solution or the dispersion system;
depositing a second solid raw material, which is formed by removing the solvent or the dispersion medium from the solution or the dispersion system, in the container; and
sublimating the second solid raw material by heating the second solid raw material deposited in the container, to generate a reactive gas.
